(19) United States
(12) Patent Application Publication
(10) Pub. No.: US 2009/0084434 A1
(43) Pub. Date: Apr. 2, 2009

(54) NANOCOMPOSITE AND METHOD OF FABRICATING THE SAME AND DYE-SENSITIZED SOLAR CELL USING THE NANOCOMPOSITE

(75) Inventors: Jong Hyeok PARK, Daejeon-city (KR); Man Gu Kang, Daejeon-city (KR); Yong Seok Jun, Daejeon-city (KR); Seung Yup Lee, Gyeongsan-city (KR); Ho Gyeong Yun, Seoul (KR); Hunkyun Pak, Daejeon-city (KR); Jong Dae Kim, Daejeon-city (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon-City (KR)

(21) Appl. No.: 12/114,016

(22) Filed: May 2, 2008

(30) Foreign Application Priority Data
Oct. 1, 2007 (KR) 10-2007-0098887

(51) Int. Cl. H01L 31/04; B05D 1/16; B32B 5/08; C25D 13/02

(52) U.S. Cl. 136/252; 204/471; 427/240; 428/119; 977/773

(57) ABSTRACT

Provided is a nanocomposite. The nanocomposite includes a plurality of nanotubes arranged perpendicular to a substrate and a plurality of nanoparticles dispersed within each of the plurality of nanotubes or between adjacent ones of the plurality of nanotubes. The nanotube and the nanoparticle are formed of titanium dioxide (TiO₂), tin dioxide (SnO₂), zinc oxide (ZnO), tungsten trioxide (WO₃), or mixtures thereof. The nanoparticle has a spherical, tubular, or rod-like shape.

### CROSS-REFERENCE TO RELATED PATENT APPLICATION

This application claims the benefit of Korean Patent Application No. 10-2007-0098887, filed on Oct. 1, 2007, in the Korean Intellectual Property Office, the disclosure of which is incorporated herein in its entirety by reference.

### BACKGROUND OF THE INVENTION

1. Field of the Invention

The present invention relates to a nanocomposite and method of fabricating the same and a dye-sensitized solar cell (DSSC) using the nanocomposite. The present invention is derived from research conducted by Ministry of Information and Communication (MIC) and Institute of Information Technology Advancement (IITA) as part of efforts to develop core technologies as an IT new growth engine (Project No: 2006-S-006-02 “Component Modules for Ubiquitous Terminal”)

2. Description of the Related Art

Much research has been conducted into a dye-sensitized solar cell (DSSC) technology since development of DSSCs in 1991 by a research team led by Michael Gratzel, professor of Swiss Federal Institute of Technology at Lausanne, Switzerland. A DSSC is an electrochemical solar cell that includes an electrode with an oxide layer having dye molecules chemically absorbed onto the surface thereof. The dye molecules absorb visible rays to produce electron-hole pairs and the electrode transfers the produced electrons.

Despite an advantage of lower manufacturing costs over conventional silicon solar cells, DSSCs have low energy conversion efficiency. Since the energy conversion efficiency of the DSSC increases in proportion to the amount of electrons produced by absorbing incoming light, the number of dye molecules being absorbed on the oxide layer must be increased in order to generate more electrons. Thus, in order to increase the concentration of dye molecules absorbed per unit area, it is necessary to reduce the size of particles which form the oxide layer.

### SUMMARY OF THE INVENTION

The present invention provides a nanocomposite that can be used to fabricate a dye-sensitized solar cell (“DSSC”) as well as materials for other industry sectors and can contain an increased amount of dye molecules and other general molecules absorbed.

The present invention also provides a method of easily fabricating the nanocomposite.

The present invention also provides a DSSC using the nanocomposite as a nano oxide layer having dye molecules absorbed thereon.

According to an aspect of the present invention, there is provided a nanocomposite including: a plurality of nanotubes arranged perpendicular to a substrate and a plurality of nanoparticles dispersed within each of the plurality of nanotubes or between adjacent ones of the plurality of nanotubes. The nanotube and the nanoparticle may be formed of titanium dioxide (TiO₂), tin dioxide (SnO₂), zinc oxide (ZnO), tungsten trioxide (WO₃), or mixtures thereof. The nanoparticle may have a spherical, tubular, or rod-like shape.

According to another aspect of the present invention, there is provided a method of fabricating a nanocomposite. According to the method, a plurality of nanotubes are formed perpendicular to a substrate. A plurality of nanoparticles that will be incorporated into each of the plurality of nanotubes are then synthesized. the nanoparticles may have a diameter of less than an inner diameter of the nanotube or distance between two adjacent nanotubes. The plurality of nanoparticles are subsequently placed within the nanotube or between the adjacent nanotubes.

The nanotube may be obtained by etching the substrate or forming a conducting layer for nanotubes on the substrate and etching the conducting layer. The conducting layer for nanotubes may be formed of Ti, Sn, Zn, W, or a mixture thereof. The nanotube and the nanoparticle may be formed of TiO₂, SnO₂, ZnO, WO₃, or mixtures thereof. The plurality of nanoparticles are disposed within the nanotube or between adjacent nanotubes using electrophoresis, spin coating, or deep coating.

According to another aspect of the present invention, there is provided a DSSC including: a first electrode unit including a nanocomposite and dye molecules absorbed on the nanocomposite, the nanocomposite having a plurality of nanotubes arranged on a first substrate and a plurality of nanoparticles dispersed within each of the plurality of nanotubes or between adjacent ones of the plurality of nanotubes; a second electrode unit formed on a second substrate so as to face the first electrode unit; and an electrolytic solution interposed between the first and second electrode units.

The nanotube and the nanoparticle may be formed of TiO₂, SnO₂, ZnO, WO₃, or mixtures thereof. The nanoparticle has a spherical, tubular, or rod-like shape.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are top and perspective views of a nanocomposite according to an embodiment of the present invention;

FIG. 3 is a flowchart illustrating a method of fabricating a nanocomposite according to an embodiment of the present invention;

FIG. 4 illustrates a titanium dioxide (TiO₂) nanotube fabricated according to Examples 1 and 2 of the present invention;

FIG. 5 illustrates TiO₂ nanoparticles used in Examples 1 and 2 of the present invention;

FIG. 6 is a schematic cross-sectional view of a dye-sensitized solar cell (DSSC) according to an embodiment of the present invention;

FIG. 7 is a top view of the nanocomposite layer in FIG. 6;

FIG. 8 is a flowchart illustrating a method of fabricating a DSSC according to an embodiment of the present invention; and

FIG. 9 is a current versus voltage (I-V) graph for a DSSC according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

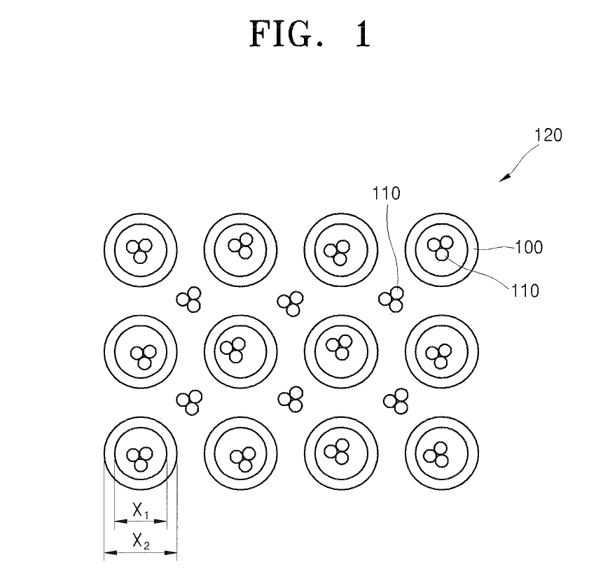

A nanocomposite according to the present invention includes a plurality of nanotubes and a plurality of nanoparticles that are dispersed within each of the plurality of nanotubes or between adjacent ones of the plurality of nanotubes and have a diameter of less than an inner diameter of each nanotube. The nanocomposite having the above-mentioned structure can be used to fabricate DSSCs as well as materials for other industry fields and facilitates charge transfer using nanotubes. The nanocomposite also provides increased surface area of nanotubes and, in particular, nanoparticles, thus increasing the amount of dye molecules as well as other general molecules absorbed. The nanocomposite having the above features will now be described in more detail with reference to FIGS. 1 and 2.

FIGS. 1 and 2 are top and perspective views of a nanocomposite 120 according to an embodiment of the present invention.

More specifically, referring to FIGS. 1 and 2, the nanocomposite 120 according to the present embodiment includes a plurality of nanotubes 100 arranged perpendicular to a substrate 10 and a plurality of nanoparticles 110 that are dispersed over various locations within each of the plurality of nanotubes 100 or between adjacent ones of the plurality of nanotubes 100 and have a diameter less than an inner diameter of the nanotube 100 or a distance between the two adjacent nanotubes 100. In general, there are many empty spaces within or between the nanotubes 100. The nanoparticles 110 can fill the empty spaces inside or between the nanotubes 100. The nanoparticles 110 are formed of semi-conducting materials. While the nanocomposite 120 shown in FIGS. 1 and 2 includes 12 nanotubes aligned in one direction for better visualization, more nanotubes 100 may be arranged in an irregular fashion across the substrate 10.

The nanotubes 100 and the nanoparticles 110 are nano oxides that may be formed of titanium dioxide (TiO₂), tin dioxide (SnO₂), zinc oxide (ZnO), or mixtures thereof. In particular, the nanotubes 100 and the nanoparticles 110 may be formed of TiO₂.

An outer diameter X₂ of the nanotube 100 is greater than 50 nm, preferably, in a range of between 50 and 300 nm. An inner diameter X₁ of the nanotube 100 is greater than 50 nm, preferably, in a range of between 50 and 200 nm. The distance between two adjacent nanotubes 100 may be greater than 50 nm. A longitudinal length of the nanotube 100 is in a range of 5 to 100 μm. The diameter of the nanoparticle 110 may be in a range of 2 to 50 nm. While the nanoparticle 110 shown in FIGS. 1 and 2 has a spherical shape, it may have a tubular or rode shape.

When the nanocomposite 120 having the above-mentioned structure is used in a DSSC as described in detail later, the nanotubes 100 having a higher charge transfer rate than the nanoparticles 1 10 can accelerate movement of electrons. In particular, nanoparticles 110 filling the empty space within the nanotube 100 can significantly increase the amount of dye molecules absorbed to the surface thereof. Thus, the use of the the nanocomposite 120 in a DSSC can significantly improve the energy conversion efficiency.

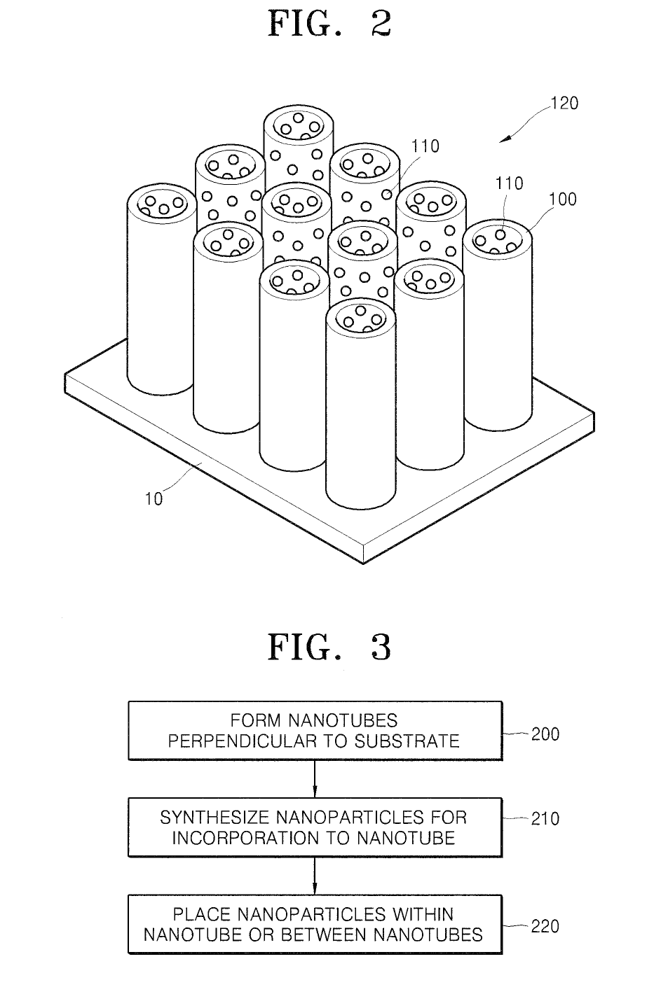

FIG. 3 is a flowchart illustrating a method of fabricating a nanocomposite according to an embodiment of the present invention.

Referring to FIG. 3, the fabrication method according to the present embodiment includes forming a plurality of nanotubes in a direction perpendicular to a substrate (step 200). The substrate may be formed of Ti, Sn, Zn, tungsten (W), or mixture thereof. The plurality of nanotubes may be fabricated by etching the substrate using anodization. Alternatively, the nanotubes may be fabricated by forming a conducting layer for nanotubes on a polymer substrate or a glass substrate and etching the conducting layer by anodization. The conducting layer for nanotubes may be formed of Ti, Sn, Zn, tungsten (W), or mixture thereof. In this way, the nanotube is formed of TiO₂, SnO₂, ZnO, tungsten trioxide (WO₃), or a mixture thereof. The nanotube has the same inner and outer diameters and longitudinal length as described above.

Subsequently, a plurality of nanoparticles to be incorporated into the nanotube are formed with a diameter of less than the inner diameter of the nanotube (step 210). The nanoparticles are synthesized using TiO₂, SnO₂, ZnO, WO₃, or mixture thereof. Each of the plurality of nanoparticles has the same diameter as described above. The plurality of synthesized nanoparticles are dispersed within the nanotube or between adjacent nanotubes using a technique such as electrophoresis, spin coating, or deep coating (step 220).

Based on the foregoing, a nanocomposite and a method of manufacturing the same according to embodiments of the present invention will now be described. In the examples below, it is assumed that nanotubes and nanoparticles are formed of TiO₂.

### EXAMPLE 1

### Method of Fabricating Nanocomposite

More specifically, after a Ti foil substrate was dipped into a mixture of acetone and alcohol, fine foreign materials and an oxide layer were removed using ultrasonic waves and 0.1% HF solution, respectively. To obtain TiO₂ nanotube, a Ti foil sample was dipped into a solution of ethylene glycol containing 0.25% ammonium fluoride (NH₄F) and then a voltage of 50 V was applied using platinum (Pt) as a counter electrode to etch the sample by anodization. After performing the etching for about 10 hours, the sample was cleaned with acetone and alcohol to form a TiO₂ nanotube.

Subsequently, a TiO₂ nanoparticle was synthesized. More specifically, 0.5 mole (M) titanium tetrachloride (TiCl₄) aqueous solution was formed at 0° C., followed by hydrolysis of TiCl₄ at room temperature for 1 week such that white TiO₂ powder was produced. The TiO₂ powder sedimented in the aqueous solution was then recovered using a rotary evaporator and redispersed in a distilled water. The resulting TiO₂ aqueous solution was evaporated again using the rotary evaporator to synthesize a white TiO₂ nanoparticle. The synthesized TiO₂ nanoparticles have a diameter of less than an inner diameter of a nanotube or distance between nanotubes into which they will be later incorporated.

After synthesizing the TiO₂ nanoparticles, a TiO₂ nanotube was submerged in the aqueous solution in which the TiO₂ nanopartcles had been dispersed and then a voltage of 10V was applied such that the TiO₂ nanopartcles were incorporated into the TiO₂ nanotube. Although in the present Example, electrophoresis was performed to incorporate the TiO₂ nanopartcles into the TiO₂ nanotube, spin coating or deep coating may be used to achieve the same effect. Electrophoresis is preferred over other techniques.

The resulting material with the TiO₂ nanopartcles incorporated into the TiO₂ nanotube was then heat treated at 500° C. for 30 minutes under an air atmosphere. After the resulting product was dipped into the TiCl₄ solution at 70° C., it was heat treated again at 500° C. for 30 minutes under an air atmosphere to complete a nanocomposite having the TiO₂ nanopartcles incorporated into the TiO₂ nanotube.

### EXAMPLE 2

### Method of Fabricating Nanocomposite

More specifically, Ti was sputter-coated on a substrate to a thickness of about 20 μm. The substrate may be a polymer substrate or glass substrate coated with indium titanium oxide (ITO) or fluorine (F)-doped SnO₂. As in the Example 1, the coated Ti layer was etched by anodization to form a TiO₂ nanotube.

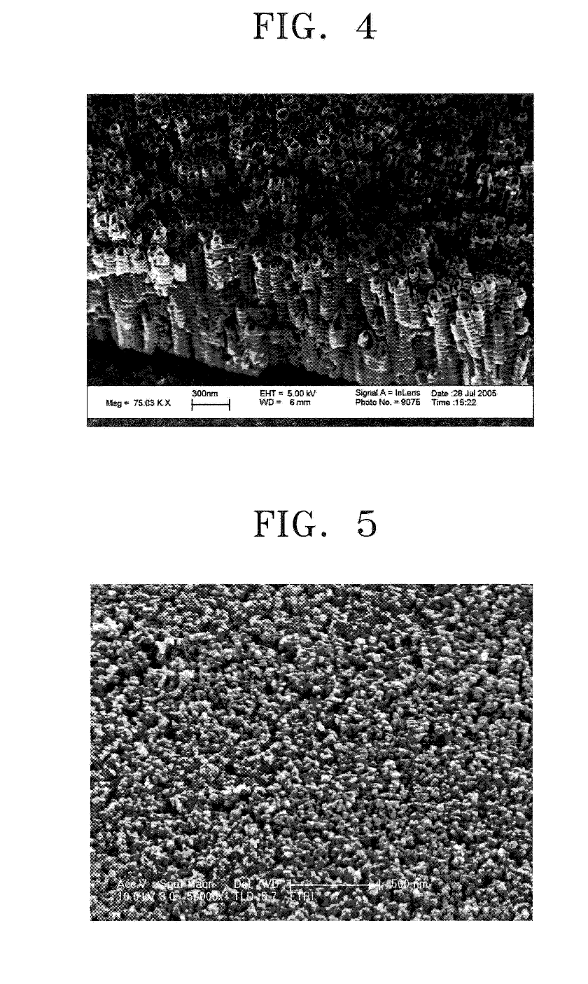

FIG. 4 illustrates a TiO₂ nanotube fabricated according to the Examples 1 and 2 of the present invention and FIG. 5 illustrates TiO₂ nanoparticles used in the Examples 1 and 2 of the present invention.

More specifically, FIGS. 4 and 5 are electron microscope photographs of TiO₂ nanotubes and TiO₂ nanoparticles. Referring to FIG. 4, a plurality of TiO₂ nanotubes according to the present invention are formed perpendicular to a substrate. Each of the plurality of TiO₂ nanotubes may have the same diameter as described earlier. In particular, FIG. 4 shows that each TiO₂ nanotube has an inner diameter of greater than 50 nm. FIG. 5 shows the TiO₂ nanoparticle is nano-sized and may have the same dimension as described earlier.

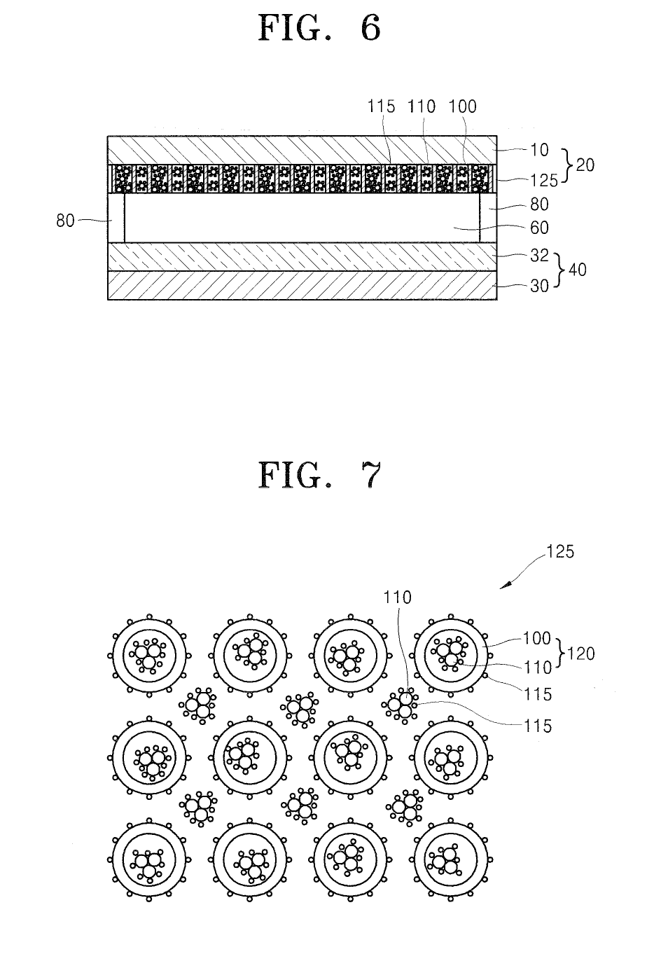

The structure of a DSSC using the nanocomposite and a method of manufacturing the same will now be described in detail with reference to FIGS. 6 and 7.

### DSSC According to Embodiment of Present Invention

FIG. 6 is a schematic cross-sectional view of a DSSC according to an embodiment of the present invention and FIG. 7 is a top view of the nanocomposite layer in FIG. 6.

More specifically, referring to FIGS. 6 and 7 the DSSC according to the present embodiment includes a first electrode unit 20, a second electrode unit 40 disposed under the first electrode unit 20 so as to face the first electrode unit 20, and an electrolytic solution 60 interposed between the first and second electrode units 20 and 40. The DSSC further includes sealing members 80 disposed at either end of the space between the first and second electrode units 20 and 40 so as to prevent (seal against) leakage of the electrolytic solution 50. The sealing members 80 may be formed of a thermoplastic polymer material.

The first electrode unit 20 includes a first substrate 10 and an overlying nanocomposite layer 125 with dye molecules 115 absorbed thereon. The first substrate 10 may be a conducting substrate such as a Ti foil or a Ti substrate coated with ITO. Alternatively, the first substrate 10 may be a polymer or glass substrate coated with ITO or F-doped SnO₂.

The nanocomposite layer 125 acts as an electrode and includes a nanocomposite 120 having a plurality of nanotubes 100 and a plurality of nanoparticles 110 as described above. The plurality of nanoparticles 110 are dispersed within each of the plurality of nanotubes or between the plurality of nanotubes and have a diameter of less than an inner diameter of each nanotube. The ruthenium (Ru)-based dye molecules 115 are chemically absorbed on the nanocomposite 120.

The second electrode unit 40 is disposed under the first electrode unit 20 to face the first electrode unit 20 and includes a second substrate 30 and a Pt electrode layer 32 facing the nanocomposite layer 125 in the first electrode unit 20. The second substrate 30 may be a conducting substrate with a Ti layer formed on a glass or polymer substrate. Either of the first or second substrate 10 or 30 may be a transparent substrate.

An acetonitrile solution containing 0.6 M butylmethylimidazolium, 0.02 M iodine I₂), 0.1M Guanidinium thiocyanate, and 0.5M 4-tert-butylpyridine may be used as the electrolytic solution 60 filled between the first and second electrode units 20 and 40.

Next, operation of the DSSC according to an embodiment of the present invention is described.

More specifically, dye molecules attached to the nanocomposite 125 absorbs sunlight using light penetrating through the transparent first substrate 10, to excite electrons from ground state into excited state and create an electron-hole pair. The excited electrons are then injected into a conduction band of the nanocomposite layer 125.

The electrons that have been injected into the nanocomposite layer 125 are transferred to the first conducting substrate 10 in contact with the nanocomposite layer 125 via an interface between particles and then move to the Pt electrode layer 32 in the second electrode unit 40 through an external wire (not shown). The dye molecules oxidized due to electron transfer receive electrons supplied by oxidation (3I⁻¹→I₃⁻+2e⁻) of iodine (I) ion within the electrolytic solution 60 to undergo reduction. The oxidized iodine ion I₃⁻ gains electrons from the second electrode unit 40 and becomes reduced again, thereby completing the operation of the DSSC.

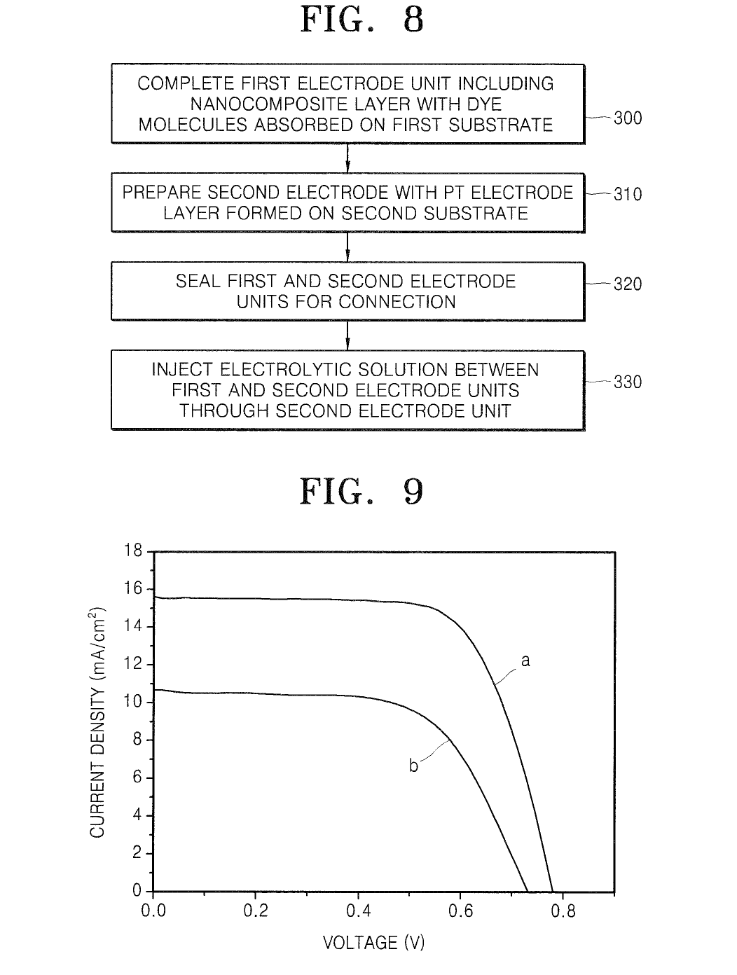

FIG. 8 is a flowchart illustrating a method of fabricating a DSSC according to an embodiment of the present invention.

More specifically, referring to FIG. 8, a nanocomposite layer is formed on a first substrate as described above. The nanocomposite layer includes a nanocomposite with dye molecules absorbed thereon. Since the nanocomposite layer is fabricated according to the method as described above, detailed description thereof is not given. To attach the dye molecules to the nanocomposite, the nanocomposite is dipped into an alcohol solution containing the dye molecules for 24 hours. In this way, a first electrode unit including the nanocomposite layer with dye molecules absorbed onto the first substrate is completed (step 300).

A second electrode with a Pt electrode layer formed on a second substrate is subsequently prepared (step 310). The Pt electrode layer is formed by coating Pt on the second substrate. Thereafter, the first and second electrode units are sealed with a sealing member for connection, followed by injection of an electrolytic solution between the first and second electrode units through the second electrode unit. In this way, a DSSC is fabricated (step 330).

DSSCs including nanocomposites fabricated according to the Example 1 and Example 2 are hereinafter referred to as a “DSSC of Example 1” and a “DSSC of Example 2”, respectively.

### COMPARATIVE EXAMPLE 1

### DSSC

More specifically, a DSSC according to the Comparative Example 1 has the same configuration as the DSSC of the Example 1 except that it includes a nanocomposite having only a plurality of TiO₂ nanotubes. That is, the nanocomposite in the DSSC according to the Comparative Example 1 does not include TiO₂ nanoparticles.

### COMPARATIVE EXAMPLE 2

### DSSC

More specifically, a DSSC according to the Comparative Example 2 has the same configuration as the DSSC of the Example 2 except that it includes only a plurality of TiO₂ nanoparticles having a thickness of about 10 μm. That is, the nanocomposite in the DSSC according to the Comparative Example 2 does not include TiO₂ nanotubes. The first substrate used in the Comparative Example 2 is a glass substrate coated with F-doped SnO₂.

Tables 1 and 2 below respectively show comparisons between DSSCs of the Example 1 and the Comparative Example 1 and between DSSCs of the Example 2 and the Comparative Example 2.

More specifically, the following Table 1 shows a comparison between surface areas of nanocomposite in the DSSC of Example 1 and TiO₂ nanotube of the Comparative Example 1. As evident from Table 1, the surface area of the nanocomposite is increased by about 20% compared to the surface area of the TiO₂ nanotube. This means the area of the dye molecules that can be absorbed in the DSSC of Example 1 is increased about 20% compared to that in the DSSC of Comparative Example 1. Thus, the DSSC of Example 1 can provide improved cell performance over the DSSC of Comparative Example 1.

TABLE 1

| Condition | Comparative Example 1 | Example 1 |
|---|---|---|
| Surface area | 400 m²/g | 480 m²/g |

The following Table 2 shows a comparison between energy conversion efficiency of DSSCs of Examples 1 and 2 and Examples. As evident from Table 2, energy conversion efficiency in the DSSCs of the Examples 1 and 2 is improved by about 20% and 10% compared to those in the DSSC of the Comparative Examples 1 and 2, respectively.

TABLE 2

| | | | Comparative | Comparative |
|---|---|---|---|---|
| Condition | Example 1 | Example 2 | Example 1 | Example 2 |
| Energy | 6.1% | 7.1% | 4.5% | 4.6% |
| conversion | | | | |
| efficiency | | | | |

Based on the result of comparisons, the DSSCs of Examples 1 and 2 using nanocomposites including both TiO₂ nanotubes and TiO₂ nanoparticles as an electrode provide improved cell efficiency over the DSSCs of Comparative Examples 1 and 2 using either TiO₂ nanotubes or TiO₂ nanoparticles as an electrode. The DSSCs of Examples 1 and 2 according to the present invention deliver improved cell efficiency because of their fast charge transfer exhibited by TiO₂ nanotubes and large surface areas exhibited by TiO₂ nanoparticles.

FIG. 9 is a current versus voltage (I-V) graph for a DSSC according to an embodiment of the present invention.

More specifically, as indicated by curve (a) on the I-V graph, a DSSC of Example 1 exhibits current density of about 15.5 mA/cm² and voltage of about 0.78 V. On the other hand, as indicated by curve (b), a DSSC of Comparative Example 2 exhibits current density of about 10.7 mA/cm² and voltage of about 0.73 V. That is, the DSSC of Example 1 including both TiO₂ nanotubes and TiO₂ nanoparticles shows better current-voltage characteristics than the DSSC of Comparative Example 1 because of its fast charge transfer exhibited by the TiO₂ nanotubes and large surface area exhibited by TiO₂ nanoparticles

As described above, a nanocomposite according to the present invention includes a plurality of nanotubes and a plurality of nanoparticles that are dispersed within each nanotube or between adjacent nanotubes and have a diameter of less than an inner diameter of the nanotube. The nanocomposite having the above-mentioned structure facilitates electron movement while providing increased surface area of nanotubes and, in particular, nanoparticles so that the amount of absorbed general molecules can be increased.

When the nanocomposite is used in a DSSC, nanotubes in the nanocomposite can accelerate movement of electrons and nanotubes and nanoparticles (in particular, nanoparticles) can significantly increase the amount of dye molecules. Thus, the use of the nanocomposite in the DSSC can significantly improve the energy conversion efficiency.

What is claimed is:

1. A nanocomposite comprising:
a plurality of nanotubes arranged perpendicular to a substrate; and
a plurality of nanoparticles dispersed within each of the plurality of nanotubes or between adjacent ones of the plurality of nanotubes.

2. The nanocomposite of claim 1, wherein the nanotubes and the nanoparticles are formed of a compound selected from the group consisting of titanium dioxide (TiO₂), tin dioxide (SnO₂), zinc oxide (ZnO), tungsten trioxide (WO₃), and mixtures thereof.

3. The nanocomposite of claim 1, wherein each of the plurality of nanotubes has an outer diameter of 50 to 300 nm and an inner diameter of 50 to 200 nm and each of the plurality of nanoparticles has a size of 2 to 50 nm.

4. The nanocomposite of claim 1, wherein the nanoparticle has a spherical, tubular, or rod-like shape.

5. A method of fabricating a nanocomposite, comprising:
forming a plurality of nanotubes perpendicular to a substrate;
synthesizing a plurality of nanoparticles that will be incorporated into each of the plurality of nanotubes, the nanoparticles having a diameter of less than an inner diameter of the nanotube or distance between two adjacent nanotubes; and
disposing the plurality of nanoparticles within the nanotube or between the adjacent nanotubes.

6. The method of claim 5, wherein the nanotube is formed by etching the substrate or a conducting layer for nanotubes formed on the substrate.

7. The method of claim 6, wherein the conducting layer for nanotubes is formed of a material selected from the group consisting of titanium (Ti), tin (Sn), zinc (Zn), tungsten (W), and mixtures thereof, and
wherein the nanotube is formed of a compound selected from the group consisting of titanium dioxide (TiO₂), tin dioxide (SnO₂), zinc oxide (ZnO), tungsten trioxide (WO₃), and mixtures thereof.

8. The method of claim 5, wherein the nanoparticle is formed of a compound selected from the group consisting of TiO₂, SnO₂, ZnO, WO₃, and mixtures thereof.

9. The method of claim 5, wherein the plurality of nanoparticles are disposed within the nanotube or between adjacent nanotubes using electrophoresis, spin coating, or deep coating.

10. A dye-sensitized solar cell (DSSC) comprising:
a first electrode unit including a nanocomposite and dye molecules absorbed on the nanocomposite, the nanocomposite having a plurality of nanotubes arranged on a first substrate and a plurality of nanoparticles dispersed within each of the plurality of nanotubes or between adjacent ones of the plurality of nanotubes;
a second electrode unit formed on a second substrate so as to face the first electrode unit; and
an electrolytic solution interposed between the first and second electrode units.

11. The DSSC of claim 10, wherein the nanotube and the nanoparticle are formed of a compound selected from the group consisting of TiO₂, SnO₂, ZnO, WO₃, and mixtures thereof.

12. The DSSC of claim 10, wherein each nanotube has an outer diameter of 50 to 300 nm and an inner diameter of 50 to 200 nm and each nanoparticle has a size of 2 to 50 nm.

13. The nanocomposite of claim 10, wherein the nanoparticle has a spherical, tubular, or rod-like shape.
